(19) United States
(12) Patent Application Publication
(10) Pub. No.: US 2025/0066911 A1
(43) Pub. Date: Feb. 27, 2025

(54) METHOD OF USING A THERMAL LASER EVAPORATION SYSTEM AND THERMAL LASER EVAPORATION SYSTEM

(71) Applicant: MAX-PLANCK-GESELLSCHAFT ZUR FÖRDERUNG DER WISSENSCHAFTEN E.V., München (DE)

(72) Inventor: Wolfgang BRAUN, Bietigheim-Bissingen (DE)

(21) Appl. No.: 18/729,560

(22) PCT Filed: Jan. 20, 2022
(86) PCT No.: PCT/EP2022/051198

§ 371 Date: Jul. 17, 2024

(51) Int. Cl. C23C 16/448; B23K 26/06; B23K 26/073; B23K 26/12; B23K 26/362

(52) U.S. Cl. CPC C23C 16/4485; B23K 26/0608; B23K 26/0626; B23K 26/073; B23K 26/1224; B23K 26/126; B23K 26/362

(57) ABSTRACT

The invention is related to a method of using a thermal laser evaporation (TLE) system (100), the system (100) comprising a reaction chamber (10) fillable with a reaction atmosphere (14), one or more sources (30) arranged in the reaction chamber (10), each source (30) comprising a source material (32), and a laser source (50) for providing laser radiation (52) at a surface (34) of the source (30) and thereby evaporating the source material (32). Further, the invention is related to a thermal laser evaporation system (100) comprising a reaction chamber (10) fillable with a reaction atmosphere (14), one or more sources (30) arranged in the reaction chamber (10), each source comprising a source material (32), and coupling means (12) provided by the reaction chamber (10) for coupling laser radiation (52) into the reaction chamber (10) for impinging on a surface (34) of the source (30) and thereby evaporating the source material (32).

The invention relates to a method of using a thermal laser evaporation system, the system comprising a reaction chamber fillable with a reaction atmosphere, one or more sources arranged in the reaction chamber, each source comprising a source material, and a laser source for providing laser radiation at a surface of the source and thereby evaporating the source material. Further, the invention is related to a thermal laser evaporation system comprising a reaction chamber fillable with a reaction atmosphere, one or more sources arranged in the reaction chamber, each source comprising a source material, and coupling means provided by the reaction chamber for coupling laser radiation into the reaction chamber for impinging on a surface of the source and thereby evaporating the source material.

In thermal laser evaporation (TLE), material is evaporated in a controlled environment, in particular in a reaction chamber filled with a reaction atmosphere, by means of laser heating, usually with the intent to coat a surface with a thin film. The efficiency of TLE relies on the local heating of the source surface, since the growth rate increases exponentially with the power density within the laser irradiated spot.

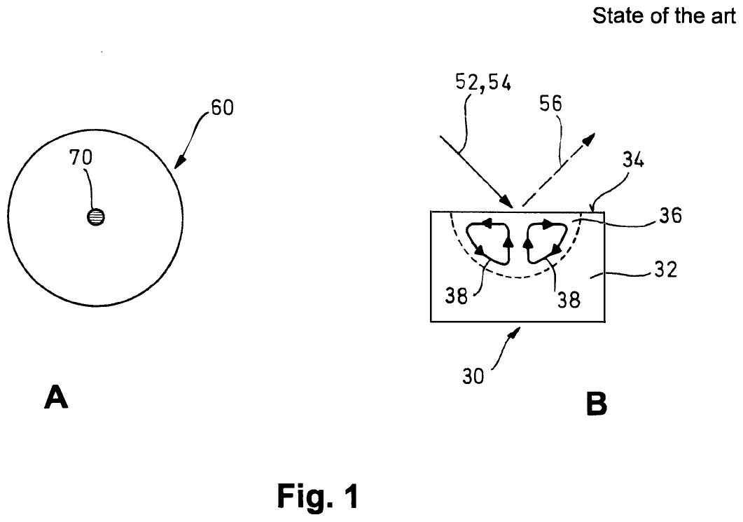

Such a single heating spot 70, forming a laser intensity pattern 60 of highest simplicity, is depicted on the left half of FIG. 1, denoted with “A”. When heated locally by a laser beam 54, in general by laser radiation 52, a solid block of source material 32 of the source 30 to be evaporated forms a spatially confined melt volume 36, either within the source material 32 itself as delineated by the dashed arc in the right image of FIG. 1, denoted with “B”, or within a containing crucible.

As already depicted in image “B” of FIG. 1, the melted source material 32 forms convection currents 38 within the melt volume 36. Convection currents 38 are usually driven by the lower density of thermally expanded liquid at higher temperatures, leading to an upward movement of the lighter liquid in a gravitational field, and a downward movement of colder, denser source material 32. Depending on the properties of the source material 32, the direction of flow may also be opposite, and the details of the process may differ significantly between different source materials and for different boundary conditions.

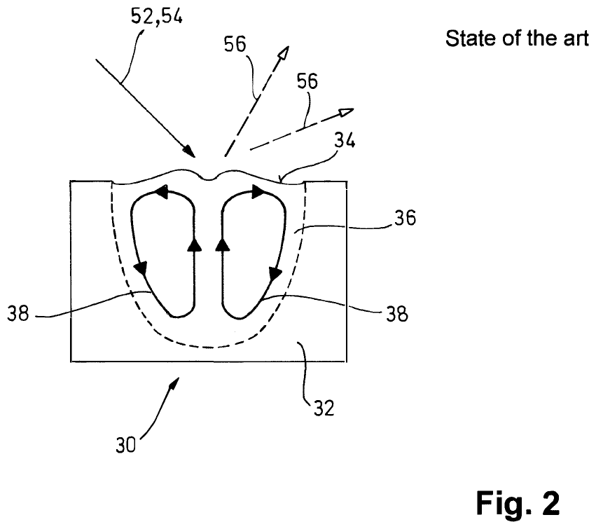

In FIG. 2, the evaporation process of image “B” of FIG. 1 is depicted in a later state. As shown, said convection currents 38 often lead to disturbances of the evaporation process. In particular, strong convection currents 38 may transport significant amounts of source material 32 and thereby increase both the diameter and in particular the depth of the melt volume 36. In particular, strong convection currents 38 can produce height differences with mounds and valleys on the surface 34 of the melt volume 36 within the source 30. These may become turbulent and unstable, possibly amplified by non-uniform heating of the dynamically tilting, differently inclined elements of the surface 34 by the impinging laser beam 54, indicated in FIG. 2 by the two different dashed arrows representing the reflected laser beam 56. At high power densities, this may lead to unstable evaporation, even splattering of droplets, and thereby defects and nonuniformities in the deposited films.

In view of the above, it is an object of the present invention to provide an improved method of using a thermal laser evaporation system and an improved thermal laser evaporation system which do not have the aforementioned drawbacks of the state of the art. In particular, it is an object of the present invention to provide an improved method of using a thermal laser evaporation system and an improved thermal laser evaporation system, which allow stable, high-flux evaporation from a large surface area.

This object is satisfied by the respective independent patent claims. In particular, this object is satisfied by a method of using a thermal laser evaporation system according to independent claim 1 and by a thermal laser evaporation system according to independent claim 20. The dependent claims describe preferred embodiments of the invention. Details and advantages described with respect to a method according to the first aspect of the invention also refer to a thermal laser evaporation system according to the second aspect of the invention, and vice versa, if of technical sense.

According to the first aspect of the invention, the object is satisfied by a method of using a thermal laser evaporation (TLE) system, the system comprising a reaction chamber fillable with a reaction atmosphere, one or more sources arranged in the reaction chamber, each source comprising a source material, and a laser source for providing laser radiation at a surface of the source and thereby evaporating the source material, wherein the laser radiation has a spatially modulated intensity pattern, wherein the spatially modulated intensity pattern comprises two or more spaced apart heating spots with an at least locally maximal intensity.

The method according to the first aspect of the present invention is intended for the usage of a thermal laser evaporation system, or short of a TLE system. Such systems are already known in general. A laser beam provided by a laser source is used for evaporating a source material, in most of the cases for a deposition of the evaporated source material onto a substrate provided as target. In most of the cases, the deposition of the laser energy onto the surface of the source causes the source material to melt forming a melt volume of liquid source material. However, in the scope of the present invention, the expression evaporation process also covers the process of sublimation of the source material.

The source is arranged within a reaction chamber, which is sealable against ambient atmosphere and fillable with a reaction atmosphere. Said reaction atmosphere can be vacuum, in particular as low as 10⁻¹² hPa or even lower, or comprise reaction gases at pressures suitable for the material to be deposited, for instance a reaction gas providing oxygen for a deposition of an oxide of an evaporated source material. Maximum values tested with a working distance of 60 mm so far are as high as 10⁻¹ hPa. Still higher values are likely possible as deposition was possible without problems at 10⁻² hPa.

The laser radiation is coupled in most of the cases into the reaction chamber via coupling means. Said coupling means can be for instance simple windows in a chamber wall of the reaction chamber. However, coupling means according to the present invention can also comprise adaptive optics for forming the laser radiation impinging on the surface of the source material.

In the method according to the first aspect of the present invention the laser radiation has a spatially modulated intensity pattern. In particular, said spatially modulated intensity pattern comprises two or more spaced apart heating spots with an at least locally maximal intensity.

Preferably, a heating spot according to the present invention is circular, in particular having a circularly symmetric Gaussian intensity profile, for instance provided by focusing the laser radiation onto the surface of the source material. Spot sizes, preferably defined as full width half max values of the Gaussian profile, with diameters less than 10 mm, preferably less than 1 mm, can be provided.

An at least locally maximal intensity of the laser radiation at one of the heating spots means in the sense of the present invention that said heating spots are surrounded by an area within the intensity pattern, where the intensity of the laser radiation is lower or at maximum equal compared to the intensity of the laser radiation at the heating spot. In other words, in the area surrounding each heating spot, the intensity of the laser radiation is nowhere higher than at the heating spot itself.

In particular, the intensity of the laser radiation at at least one of the two or more heating spots is the maximum intensity reached within the spatially modulated intensity pattern as a whole. In other words, according to the present invention local maxima of the laser radiation intensity are reached at the positions of at least one of the two or more heating spots.

In summary, by implementing a method according to the first aspect of the present invention, providing the laser radiation with a single heating spot is prohibited. The energy deposition from the laser radiation into the source material is distributed over a larger area of the surface of the source material. In addition, the different energy densities and therefore temperature maxima defined by this pattern create temperature maxima and minima, and therefore buoyancy centers, the sizes and positions of which follow the modulation of the laser light pattern.

Said forming of a temperature pattern leads to a size reduction of the cells formed by the convection currents in the melt volume formed in the source material. This reduces the depth of the convection zone, and thereby the depth of the melt volume, allowing flatter sources that do not melt through as easily.

In addition, also a spatial localization of the convection cells can be achieved. With the same surface tension, smaller convection cells result in smaller disturbances of the surface, and therefore an improved resistance against turbulence and splattering of the source. In other words, a uniformity of the flux of evaporated source material can be increased.

Simultaneously, an area of the surface of the source material melted during the evaporation process can be increased. As said area takes part as a whole in the evaporation process, a flux of evaporated source material can be increased.

In summary, by implementing the method according to the first aspect of the present invention for use with a TLE system, it is possible to define and stabilize a convection pattern in the liquid melt volume of the source or the source material. This leads to a high-flux evaporation from a large surface area with increased uniformity and hence allows high and uniform total deposition fluxes.

Further, the method according to the first aspect of the present invention can be characterized in that the laser radiation intensity is at least essentially equal or equal at the two or more heating spots. Hence, also the energy deposition from the laser radiation into the source material is at least essentially equal or equal at said heating spots. A uniformity of the convection pattern and hence the resistance against turbulence and splattering of the source can be increased further.

According to an alternative embodiment of the method according to the first aspect of the present invention, the laser radiation intensity is different at the two or more heating spots for each of the one or more sources. Hence, also the energy deposition from the laser radiation into the source material is different at said heating spots. A specific shaping of the convection pattern can thereby be provided.

In addition, the method according to the first aspect of the present invention can be characterized in that the thermal laser evaporation system comprises two or more sources, and wherein the spatially modulated intensity pattern is at least essentially equal or equal for at least two of the two or more sources. Therefore, even if more than one source is used for evaporation, the energy deposition for each of the sources can be equalized. In particular, but not limited, for sources providing the same source material, a uniform evaporation of source material from all sources present in the TLE system can be provided.

Alternatively, or additionally, the method according to the first aspect of the present invention can comprise that the thermal laser evaporation system comprises two or more sources, and wherein the spatially modulated intensity pattern is different for at least two of the two or more sources. Therefore, if more than one source is used for evaporation, the energy deposition for each of the sources can be set specifically. In particular, each source can preferably comprise its own source material. In other words, the source materials provided by the different sources are different. As a non-restrictive example, a first source can provide Titanium as source material, a second source Niobium and a third source Tantalum. By providing different spatially modulated intensity patterns for the different sources, specific boundary conditions, such as for instance a melting temperature of the respective source material, can be considered. A uniform and in particular simultaneous evaporation of different source materials can thereby be provided.

According to another embodiment of the method according to the first aspect of the present invention, the two or more heating spots are connected within the spatially modulated intensity pattern by a line-shaped heating line of at least locally maximal intensity, wherein a first end of the heating line is connected to one of the two heating spots and a second end of the heating line is connected to the other of the two heating spots. In other words, according to this embodiment between said heating spots extends a heating line within the intensity pattern of also at least locally maximal intensity of the laser radiation. Hence, also an energy deposition into the source material is increased along said heating line. In summary, shaping and controlling the convection pattern in the liquid melt volume can be increased.

In particular, each heating line with at least locally maximal intensity of laser radiation can be described as connecting two heating spots at its respective end points.

Also closed heating lines within the intensity pattern are possible. Along such a closed heating line two heating spots can be defined at arbitrary positions which are consequently and automatically connected by the closed heating line.

In addition, the method according to the first aspect of the present invention can be enhanced further by that the laser radiation intensity along the heating line gradually, in particular monotonously, changes from the intensity of the heating spot at the first end of the heating line into the intensity of the heating spot at the second end of the heating line. By providing a gradually, in particular monotonously, changing intensity along said heating line, an erratic or step-like change of intensity along the heating line can be prohibited. Forming a uniform convection pattern can thereby be ensured more easily. A gradual change according to the present invention comprises only smooth intensity changes along the heating line, wherein a monotonous change additionally demands that the intensity of the laser radiation along the heating line only decreases or only increases or stays constant along the complete heating line.

Further, the method according to the first aspect of the present invention can be characterized in that the heating line is at least partly straight and/or curved and/or shaped in the form of a circular arc. This listing contains the preferred shapes of the heating lines, however also other shapes and combinations of shapes are possible. In particular, the shape of the respective heating line can be selected with respect to boundary conditions of the present evaporation processes and/or the intended convection pattern, in particular with respect to the used source material.

According to another embodiment of the method according to the first aspect of the present invention, the spatially modulated intensity pattern is rotationally symmetric about a point of symmetry. By providing a rotationally symmetric spatially modulated intensity pattern, also the resulting convection pattern will be rotationally symmetric. A uniformity of the flux of the evaporated source material can thereby be enhanced. Further, also sources and/or the provided source materials often comprise such a rotational symmetry about a point or axis of symmetry. Adapting the intensity pattern of the laser radiation to the shape of the source and/or the provided source material can thereby be simplified.

The method according to the first aspect of the present invention can be enhanced further by that the spatially modulated intensity pattern is rotationally symmetric by an angle of 30° and/or 45° and/or 60° and/or 72° and/or 90° and/or 135° and/or 180°. This listing contains the preferred angles of rotational symmetry, however also other angles are possible.

According to another embodiment of the method according to the first aspect of the present invention, the spatially modulated intensity pattern is periodic. In a periodic intensity pattern, a small building block containing a few elements such as a heating spot or a heating line in a fixed arrangement relative to each other, is repeated one, two or more times to form the intensity pattern as a whole. Thereby, the distance and relative orientation between the elements of adjacent building blocks is kept constant. Forming a uniform convection pattern can thereby be ensured more easily.

According to an alternative embodiment of the method according to the first aspect of the present invention, the spatially modulated intensity pattern is quasi-periodic. Also, in a quasi-periodic intensity pattern, a small building block containing a few elements such as a heating spot or a heating line is repeated one, two or more times to form the intensity pattern as a whole. However, the distance and relative orientation between adjacent building blocks, and optionally also an internal arrangement of the elements of the building block, are altered, in most of the cases increased, depending on a distance to selected fix elements. Said fix elements can be preferably a point or mirror plane or axis of symmetry for providing an overall rotationally or inversion symmetric intensity pattern. Forming a convection pattern with a spatial dependence, in particular a radial dependence, can thereby be provided more easily.

According to yet another alternative embodiment of the method according to the first aspect of the present invention, the spatially modulated intensity pattern is aperiodic. An intensity pattern of any shape can thereby be provided.

As a particular example, an aperiodic intensity pattern in the sense of the present invention in particular covers also an intensity pattern which is aperiodic in its entirety, but periodic and/or quasi-periodic in its components. In particular, for a TLE system with several sources, each source with its own source material, the component of the intensity pattern dedicated for each of the sources can be periodic, symmetric and/or quasi-periodic depending on the needs of the respective source material, wherein the intensity pattern in its entirety is aperiodic.

Further, the method according to the first aspect of the present invention can be characterized in that, within the spatially modulated intensity pattern, the laser radiation intensity is at least essentially zero or zero outside of the heating spots and/or the heating line. In other words, the intensity pattern has sharp, abrupt boundaries between areas with at least locally maximal intensity and all other areas. In particular, a localized energy deposition into the source material can thereby be provided. In most of the cases this provides a high control over the convection pattern.

As an alternative, the method according to the first aspect of the present invention can comprise that, within the spatially modulated intensity pattern, the laser radiation intensity is gradually reduced, in particular gradually reduced to zero, outside of the heating spots and/or the heating line. For example, the intensity can be reduced depending on a distance to the respective heating spot and/or the heating line, in particular proportional, polynomial or any suitable monotonous functional dependency to said distance. In other words, the intensity pattern comprises smoothly modulated intensity variations. Hence, abrupt changes in energy deposition into the source material can thereby be prohibited. This can lead to a higher uniformity of the formed convection pattern. In addition, said gradual reduction of laser radiation intensity can often be provided more easily compared to an abrupt drop of the intensity to zero.

In addition, the method according to the first aspect of the present invention can comprise that the spatially modulated intensity pattern is selected with respect to the source material. By selecting the respective intensity pattern with respect to the source material, the properties of the source material and hence the resulting boundary conditions for the evaporation process can be considered. A uniform convection pattern and hence a high flux of evaporated source material can thereby be provided more easily.

Further, the method according to the first aspect of the present invention can be enhanced by that selecting the spatially modulated intensity pattern with respect to the source material is based on calculations and/or simulations. Calculations and/or simulations can be provided for a wide variety of source materials and/or different shapes of the sources. Finding and defining the most suitable intensity pattern for the laser radiation can thereby be provided in an easy and especially fast and low-cost way.

Alternatively, or additionally, the method according to the first aspect of the present invention can be characterized in that selecting the spatially modulated intensity pattern with respect to the source material is based on experimental results. By using experimental results for selecting the most suitable intensity pattern, already consolidated knowledge can be implemented in the selection process. In particular, the experimental results can be obtained in the same environment, for instance with respect to the reaction atmosphere to be used and/or in the actual reaction chamber to be used. Hence, possible sources of errors based on not applicable assumptions during the selection process can be avoided.

In another possible embodiment of the method according to the first aspect of the present invention, the spatially modulated intensity pattern additionally comprises a time dependent modulation of the laser radiation intensity. Such a time dependent modulation can be for instance a simple decrease and/or increase of the overall intensity, leading for instance to a pulsed flux of evaporated source material.

However, also a time dependence of the spatial shape of the intensity pattern is possible, for instance an overall rotation or a lateral shift of the intensity pattern. Also, a complete change of the spatial shape can be implemented. A time dependent flux control, including the spatial shape of the flux of evaporated source material, can thereby be provided. This may serve to counteract instabilities or drifts that may occur during the initial heating or final cooling of the source, during flux modulations required by the process, and due to the depletion of the source.

According to the second aspect of the invention, the object is satisfied by a thermal laser evaporation system comprising a reaction chamber fillable with a reaction atmosphere, one or more sources arranged in the reaction chamber, each source comprising a source material, and coupling means provided by the reaction chamber for coupling laser radiation into the reaction chamber for impinging on a surface of the source and thereby evaporating the source material, wherein the laser source provides the laser radiation with a spatially modulated intensity pattern, and wherein the spatially modulated intensity pattern comprises two or more spaced apart heating spots with an at least locally maximal intensity.

In the thermal laser evaporation system according to the second aspect of the present invention, a laser beam provided by a laser source is used for evaporating a source material, in most of the cases for a deposition of the evaporated source material onto a substrate provided as target. In the scope of the present invention, said evaporation process also covers a sublimation of the source material. The laser radiation is coupled into the reaction chamber via coupling means. Said coupling means can be for instance simple windows in a chamber wall of the reaction chamber.

The source is arranged within the reaction chamber, which is sealable against ambient atmosphere and fillable with a reaction atmosphere. Said reaction atmosphere can be vacuum, in particular as low as 10-12 hPa or even lower, or comprise reaction gases at pressures suitable for the material to be deposited, for instance a reaction gas providing oxygen for a deposition of an oxide of an evaporated source material.

In the system according to the second aspect of the present invention, the laser radiation has a spatially modulated intensity pattern. In particular, said spatially modulated intensity pattern comprises two or more spaced apart heating spots with an at least locally maximal intensity. The two or more heating spots can also be connected within the spatially modulated intensity pattern by heating lines, the heating lines also comprising an at least locally maximal intensity.

Again, a heating spot according to the present invention preferably is circular, in particular having a circularly symmetric Gaussian intensity profile, for instance provided by focusing the laser radiation onto the surface of the source material. Spot sizes, preferably defined as full width half max values of the Gaussian profile, with diameters less than 10 mm, preferably less than 1 mm, can be provided.

An at least locally maximal intensity of the laser radiation in the sense of the present invention means that said heating spots are surrounded by an area within the intensity pattern, where the intensity of the laser radiation is lower or at maximum equal compared to the intensity of the laser radiation at the heating spot. In other words, in the area surrounding each heating spot, the intensity of the laser radiation is nowhere higher than at the heating spot itself.

In particular, the intensity of the laser radiation at at least one of the two or more heating spots is the maximum intensity reached within the spatially modulated intensity pattern as a whole. In other words, according to the present invention the highest laser radiation intensity is reached at the position of at least one of the two or more heating spots.

In summary, according to the invention a TLE system in which the laser radiation has a single heating spot is not claimed. The energy deposition from the laser radiation into the source material is distributed over a larger area of the surface of the source material. In addition, the different energy densities and therefore temperature maxima defined by this pattern create temperature maxima and minima, and therefore buoyancy centers, the sizes and positions of which follow the modulation of the laser light pattern.

Said forming of a temperature pattern leads to a size reduction of the cells formed by the convection currents in the melt volume formed in the source material. This reduces the depth of the convection zone, and thereby the depth of the melt volume, allowing flatter sources that do not melt through as easily.

In addition, also a spatial localization of the convection cells can be achieved. With the same surface tension, smaller convection cells result in smaller disturbances of the surface, and therefore an improved resistance against turbulence and splattering of the source. In other words, a uniformity of the flux of evaporated source material can be increased.

Simultaneously, an area of the surface of the source material melted during the evaporation process can be increased. As said area takes part as a whole in the evaporation process, a flux of evaporated source material can be increased.

In summary, in the system according to the second aspect of the present invention it is possible to define and stabilize a convection pattern in the liquid melt volume of the source or the source material. This leads to a high-flux evaporation from a large surface area with increased uniformity and temporal stability and hence allows high, uniform and stable total deposition fluxes.

Preferably, the thermal laser evaporation system according to the second aspect of the present invention can be characterized in that the thermal laser evaporation system is constructed to carry out a method according to the first aspect of the present invention. By that, the thermal laser evaporation system according to the second aspect of the present invention provides all features and advantages described above with respect to a method according to the first aspect of the present invention.

In another embodiment of the thermal laser evaporation system according to the second aspect of the present invention, the laser source and/or the coupling means comprise an adaptive optics for providing the laser radiation with the spatially modulated intensity pattern. Using adaptive optics is an especially easy and effective way for providing the spatially modulated intensity pattern of the laser radiation. In particular, an adaptive optics can be used to dynamically change the provided intensity pattern during operation of the TLE system. This allows to produce different convection patterns, for instance with cell shapes or sizes depending on the overall intensity of the laser radiation impinging on the surface of the source.

Further, the thermal laser evaporation system according to the second aspect of the present invention can comprise that the laser source and/or the coupling means provide the laser radiation with the spatially modulated intensity pattern as a single laser beam. In other words, the complete intensity pattern including its spatial modulation is provided as a single laser beam. Hence, an especially simple optics can be used for guiding the laser radiation into and/or within the reaction chamber and finally onto the surface of the source.

Alternatively, the thermal laser evaporation system according to the second aspect of the present invention can be characterized in that the laser source and/or the coupling means provide the laser radiation with the spatially modulated intensity pattern as two or more separate laser beams. In particular for an intensity pattern in which the intensity is at least essentially zero or zero outside of the heating spots and/or the heating lines, using two or more separate laser beams can be of advantage. In particular the zero intensity areas of the spatially modulated intensity pattern can thereby be provided more easily.

According to another embodiment of the thermal laser evaporation system according to the second aspect of the present invention, the system comprises two or more sources with each source either having the same source material or being of a different kind of source material. A wide variety of possible evaporation processes can thereby be provided. By having the same source material, the respectively evaporated source materials are combined into an overall and enhanced flux of evaporated source material. By having different source materials, a deposition of a mixture of the different source materials can be provided. Preferably, for each of the two or more sources, laser radiation comprising a specifically adapted spatially modulated intensity pattern is provided.

In addition, the thermal laser evaporation system can be characterized in that the system comprises one or more actuators for moving the one or more sources at least essentially perpendicular or perpendicular to the surface of the respective source. Preferably, for each of the one or more sources an assigned actuator is present. By moving the respective sources, a depletion of source material caused by the sublimation process, and hence a reduction of the height of the source resulting in an increase of a distance of the surface of the source and a substrate to be coated, can be compensated. Hence, a uniformity of the provided flux of sublimated source material can be provided over a prolonged period.

The invention will be explained in detail in the following by means of embodiments and with reference to the drawings in which are shown:

FIG. 1 Schematic views of an intensity pattern and of an evaporation process according to the state of the art,

FIG. 2A more detailed view of the evaporation process according to the state of the art shown in FIG. 1,

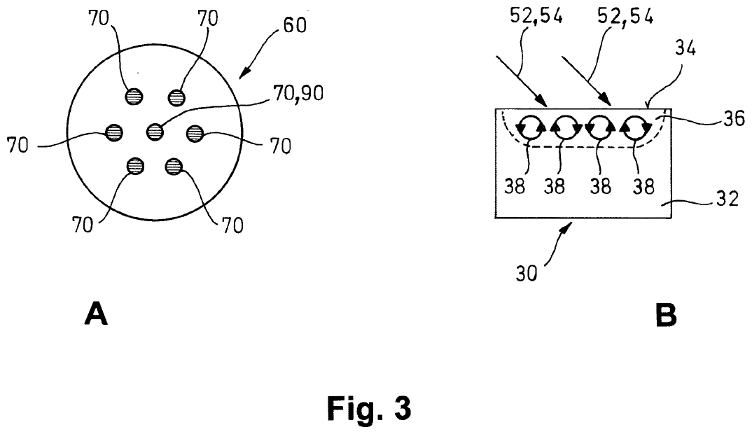

FIG. 3 Schematic views of a spatially modulated intensity pattern and of an evaporation process according to the present invention,

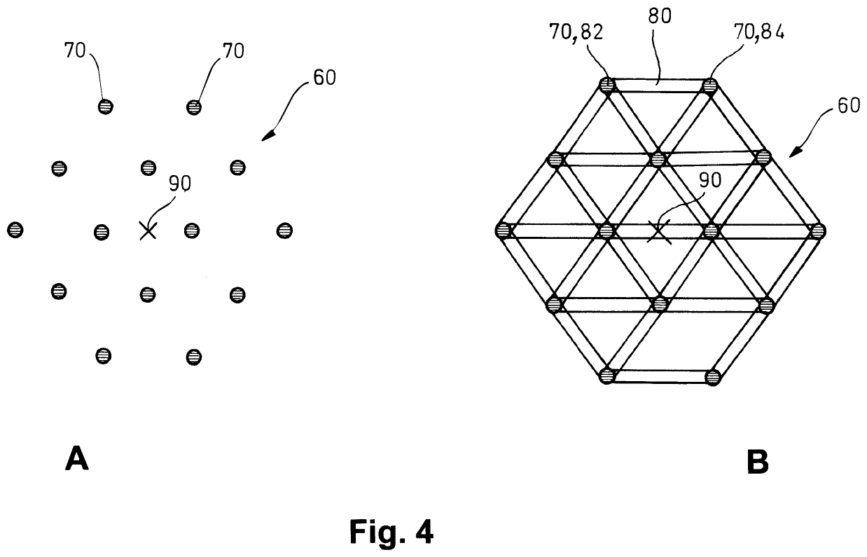

FIG. 4 Two examples of a spatially modulated intensity pattern according to the present invention,

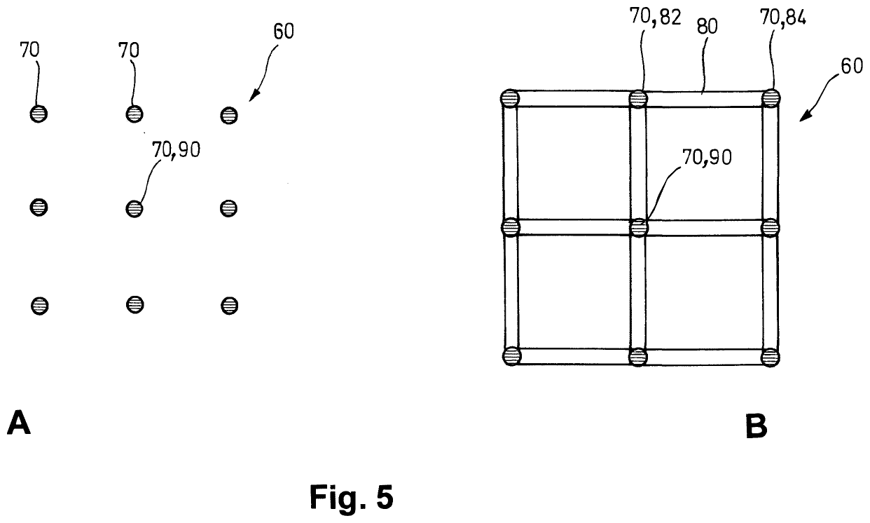

FIG. 5 Two further examples of a spatially modulated intensity pattern according to the present invention,

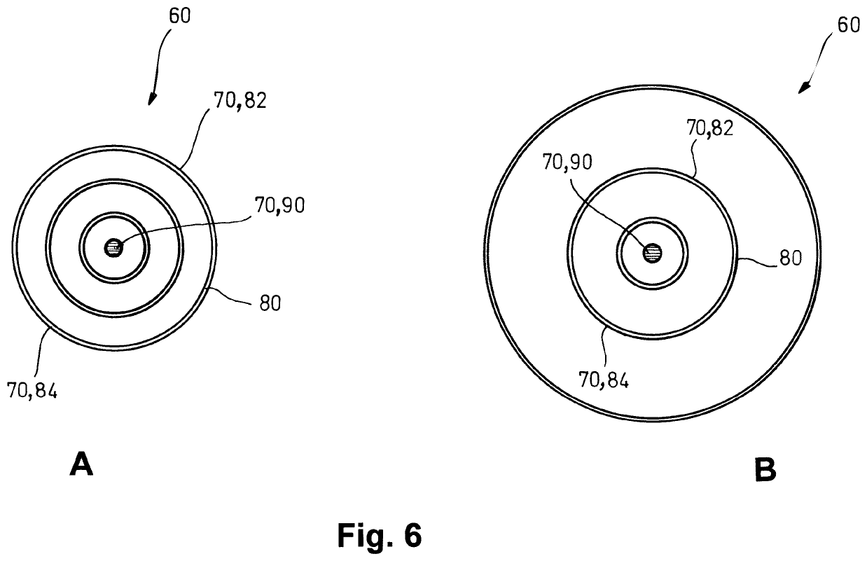

FIG. 6 Two further examples of a spatially modulated intensity pattern according to the present invention, and

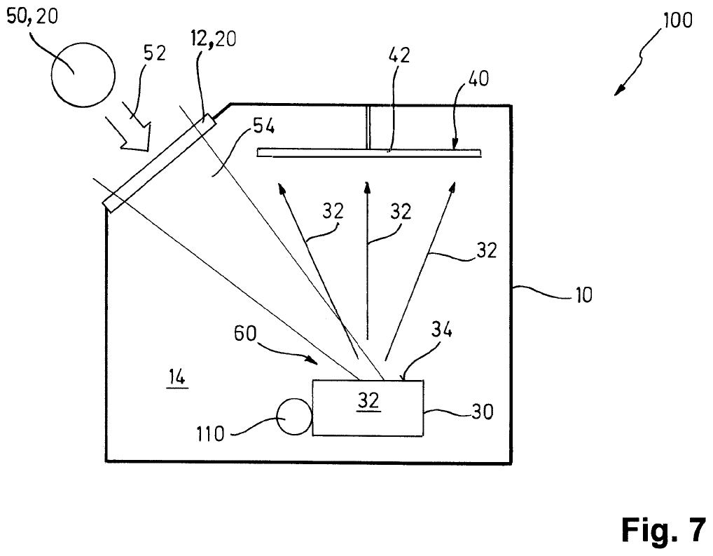

FIG. 7A schematic view of a thermal laser evaporation system according to the present invention.

FIG. 3 shows on the left side (denoted with “A”) a spatially modulated intensity pattern 60 as implemented in the method according to the present invention and provided in the system 100 (see FIG. 7) according to the present invention, and on the right side an evaporation process using said intensity pattern 60 (denoted with “B”).

The intensity pattern 60 comprises seven heating spots 70 arranged in a rotationally symmetric pattern with a rotational angle of 60°. The central heating spot 70 forms also the point of symmetry 90 of the intensity pattern 60.

Outside the heating spots 60, the intensity of the laser radiation 52 (see “B” of FIG.

3) is zero or at least close to zero. In an alternative and not depicted embodiment, also a gradual reduction of the intensity outside of the heating spots 70 is possible.

Image “B” shows a sectional side view through a source 30 consisting of source material 32. Laser radiation 52, provided as several laser beams 54, impinges onto the surface 34 of the source 32, following the intensity pattern 60 depicted in “A” of FIG. 3. This leads to a spread of the absorbed energy and several, oppositely rotating cells of convection currents 38 are formed. Compared to the situation shown in FIG. 2 for a single heating spot 70, the loops of the convection currents 38 are significantly smaller.

First of all, this reduces the depth of the melt volume 36, allowing flatter sources 32 that do not melt through as easily.

The second effect is the spatial localization of the convection cells formed by the convection currents 38. With the same surface tension, smaller convection cells result in smaller disturbances of the surface 34, and therefore an improved resistance against turbulence and splattering of the source material 32. A larger number of adjacent convection currents 38 with opposite flow directions produces a stable, and spatially pinned, undulation of the surface 34. Hence, a stable, high-flux evaporation from a large part of the surface 34 can be achieved, allowing high total deposition fluxes of the evaporated source material 32 with additionally high uniformity.

Preferably, the implemented spatially modulated intensity pattern 60 is selected with respect to the source material 32 to be evaporated. The selection can for instance be based on calculations, simulations and/or experimental results.

At the same time, the strong temperature gradient away from the outer rim of the intensity pattern 70 of the laser radiation 52 can be maintained, thereby still allowing the preferred mode of operation with a liquid melt volume 36 contained inside a solid piece of the same source material 32.

FIGS. 4 to 6 depict several possible embodiments of spatially modulated intensity patterns 70. In the following, general properties of the intensity patterns 70 provided by the present invention are described, wherein the depicted examples are included in the description.

In general, all of the depicted intensity patterns 60 comprise several heating spots 70 and/or several heating lines 80. The intensity of said heating spots 70 and/or heating lines 80 can be equal or different, depending on the actual application. For instance, in a thermal laser evaporation system 100 (see FIG. 7) with several different sources 30 comprising different source materials 32, an intensity pattern 60 suitable for each of the source materials 32 can be used, including but not limited to the implemented maximal intensity of the laser radiation 52 and of the intensity at each of the heating spots 70 and along each of the heating lines 80 and their respective spatial arrangement within the intensity pattern 60.

Additionally, to the already mentioned heating spots 70, see for instance the intensity patterns 70 denoted with “A” in FIG. 4, 5, also heating lines 80 can be part of the spatially modulated intensity patterns 60, see “B” in FIG. 4, 5 and both intensity patterns shown in FIG. 6.

Of each heating line 80, a first end 82 is connected with one heating spot 70 and a second end 84 is connected to another heating spot 70. For closed heating lines 80, as shown in FIG. 6, the respective ends 82, 84 of the heating lines 80 can be arbitrarily chosen along the respective heating line 80.

The intensity of the laser radiation 52 preferably changes gradually, in particular monotonously, along the heating line 80, from the intensity value of the heating spot 70 at the first end 82 to the intensity value of the heating spot 70 at the second end 84. However, if the intensity values of said heating spots 70 are identical, also the intensity along the heating line 80 can be constant.

As depicted in “B” of FIG. 4, 5, the heating lines 80 can be linear. Alternatively, they can also be curved and even shaped in the form of a circular arc as depicted in FIG. 6.

For providing a uniform evaporation pattern, a rotationally symmetric shape of the intensity pattern 60 about a point (2D) or axis (3D) of symmetry 90 has been found advantageous. In FIG. 4, the intensity pattern is rotationally symmetric with a rotational angle of 180°, in FIG. 5 with a rotational angle of 90°. However, as shown in FIG. 6, also intensity patterns 60 with full rotational symmetry are possible.

The intensity patterns depicted in FIG. 4, 5 are periodic. Also, the intensity pattern 60 shown in “A” of FIG. 6 is periodic in the sense of constant radial distances between the closed circular heating lines 80.

In contrast to that, also a quasi-periodic shape of the intensity pattern 60, in which for example radial distances between the closed circular heating lines 80 radially increase, are possible as depicted in “B” of FIG. 6.

As another and not explicitly depicted example, also an aperiodic embodiment of the implemented spatially modulated intensity pattern 60 is possible. In particular, in a thermal laser evaporation system 100 (see FIG. 7) with several different sources, each comprising its own source material 32, selecting a different intensity pattern 60 for each of the sources and hence an overall aperiodic intensity pattern 60 is possible.

In addition, also a time dependent modulation of the spatially modulated intensity patterns 60, in particular of the intensity patterns depicted in FIGS. 4 to 6, is possible.

FIG. 7 shows a schematic and simplified cross-sectional side view of a thermal laser evaporation system 100 according to the present invention. Within a reaction chamber 10, a source 30 and a target 40, in particular a substrate 42, are arranged. The reaction chamber 10 is filled with a reaction atmosphere 14, for instance a vacuum or a suitable reaction gas.

Via the coupling means 12, laser radiation 52 provided as one or more laser beams 54 is coupled into the reaction chamber 10 for impinging onto the surface 34 of the source 30. The laser radiation 52 is provided by a laser source 50. Adaptive optics 20, which can be part of the laser source 50 and/or of the coupling means 12, are preferably used for providing the laser radiation 52 with a spatially modulated intensity pattern 60 suitably selected for the respective source material 32.

The laser radiation 52 impinges onto the surface 34 of the source 30, and as the laser radiation 52 comprises the aforementioned spatially modulated intensity pattern 60, a high-flux evaporation of source material 32 from a large surface area can be provided. In summary, high total deposition fluxes of source material 32 (depicted as arrows in FIG. 7) at the substrate 42 can be achieved. An actuator 110 can be used to move the source 30 at least essentially perpendicular to its 10 surface 34. A compensation for the depletion of source material 32 by the sublimation process can thereby be provided.

### List of References

10 reaction chamber
12 coupling means
14 reaction atmosphere
20 adaptive optics
30 source
32 source material
34 surface
36 melt volume
38 convection current
40 target
42 substrate
50 laser source
52 laser radiation
54 laser beam
56 reflected laser beam
60 intensity pattern
70 heating spot
80 heating line
82 first end
84 second end
90 point of symmetry
100 thermal laser evaporation system

1-26. (canceled)

27. Method of using a thermal laser evaporation system, the system comprising a reaction chamber fillable with a reaction atmosphere, one or more sources arranged in the reaction chamber, each source comprising a source material, and a laser source for providing laser radiation at a surface of the source and thereby evaporating the source material,
wherein the laser radiation has a spatially modulated intensity pattern, wherein the spatially modulated intensity pattern comprises two or more spaced apart heating spots with an at least locally maximal intensity.

28. Method according to claim 27,
wherein the laser radiation intensity is at least essentially equal or equal at the two or more heating spots.

29. Method according to claim 27,
wherein the laser radiation intensity is different at the two or more heating spots for each of the one or more sources.

30. Method according to claim 27,
wherein the thermal laser evaporation system comprises two or more sources, and wherein the spatially modulated intensity pattern is at least essentially equal or equal for at least two of the two or more sources.

31. Method according to claim 27,
wherein the thermal laser evaporation system comprises two or more sources, and wherein the spatially modulated intensity pattern is different for at least two of the two or more sources.

32. Method according to claim 27,
wherein the two or more heating spots are connected within the spatially modulated intensity pattern by a line-shaped heating line of at least locally maximal intensity, wherein a first end of the heating line is connected to one of the two heating spots and a second end of the heating line is connected to the other of the two heating spots.

33. Method according to claim 32,
wherein the laser radiation intensity along the heating line gradually changes from the intensity of the heating spot at the first end of the heating line into the intensity of the heating spot at the second end of the heating line.

34. Method according to claim 32,
wherein the heating line is at least partly straight and/or curved and/or shaped in the form of a circular arc.

35. Method according to claim 27,
wherein the spatially modulated intensity pattern is rotationally symmetric about a point of symmetry.

36. Method according to claim 35,
wherein the spatially modulated intensity pattern is rotationally symmetric by an angle of 30° and/or 45° and/or 60° and/or 72° and/or 90° and/or 135° and/or 180°.

37. Method according to claim 27, wherein the spatially modulated intensity pattern is periodic.

38. Method according to claim 27, wherein the spatially modulated intensity pattern is quasi-periodic.

39. Method according to claim 27, wherein the spatially modulated intensity pattern is aperiodic. 40 (New) Method according to claim 27, wherein, within the spatially modulated intensity pattern, the laser radiation intensity is at least essentially zero or zero outside of the heating spots and/or the heating line.

41. Method according to claim 27, wherein within the spatially modulated intensity pattern the laser radiation intensity is gradually reduced outside of the heating spots and/or the heating line.

42. Method according to claim 27, wherein the spatially modulated intensity pattern is selected with respect to the source material.

43. Method according to claim 42, wherein selecting the spatially modulated intensity pattern with respect to the source material is based on calculations and/or simulations.

44. Method according to claim 42, wherein selecting the spatially modulated intensity pattern with respect to the source material is based on experimental results.

45. Method according to claim 27,
wherein the spatially modulated intensity pattern additionally comprises a time dependent modulation of the laser radiation intensity.

46. Thermal laser evaporation system comprising a reaction chamber fillable with a reaction atmosphere, one or more sources arranged in the reaction chamber, each source comprising a source material, and coupling means provided by the reaction chamber for coupling laser radiation into the reaction chamber for impinging on a surface of the source and thereby evaporating the source material, wherein the laser source provides the laser radiation with a spatially modulated intensity pattern, wherein the spatially modulated intensity pattern comprises two or more spaced apart heating spots with an at least locally maximal intensity.

47. Thermal laser evaporation system according to claim 46,
wherein the laser source and/or the coupling means comprise an adaptive optics for providing the laser radiation with the spatially modulated intensity pattern.

48. Thermal laser evaporation system according to claim 46,
wherein the laser source and/or the coupling means provide the laser radiation with the spatially modulated intensity pattern as a single laser beam.

49. Thermal laser evaporation system according to claim 46,
wherein the laser source and/or the coupling means provide the laser radiation with the spatially modulated intensity pattern as two or more separate laser beams.

50. Thermal laser evaporation system according to claim 46, wherein the system comprises two or more sources with each source either having the same source material or being of a different kind of source material.

51. Thermal laser evaporation system according to claim 46,
wherein the system comprises one or more actuators for moving the one or more sources at least essentially perpendicular or perpendicular to the surface of the respective source.
